(19) United States
(12) Patent Application Publication
(10) Pub. No.: US 2020/0132769 A1
(43) Pub. Date: Apr. 30, 2020

(54) SAS Connector Conduction Detecting System And Method Thereof

(71) Applicants: Inventec (Pudong) Technology Corporation, Shanghai (CN); Inventec Corporation, Taipei City (TW)

(72) Inventor: Yuan Sang, Shanghai (CN)

(21) Appl. No.: 16/226,315

(22) Filed: Dec. 19, 2018

(30) Foreign Application Priority Data
Oct. 29, 2018 (CN) 201811269635.6

(51) Int. Cl. G01R 31/3185; G06F 11/22

(52) U.S. Cl. CPC G01R 31/318597; G06F 11/2221; G01R 31/318572

(57) ABSTRACT

A SAS connector conduction detecting system and a method thereof are provided. A SAS connector of each of two detection circuit boards is connected to one mainboard SAS connector of the mainboard respectively, and a TAP controller and the two detection circuit boards are cascaded through the JTAG input connector and the JTAG output connector on each of the two detection circuit boards, so that the two detection circuit boards can provide the conduction detection for the mainboard SAS connectors correspondingly connected at the same time. Therefore, the improve efficiency of SAS connector conduction detection may be achieved.

### BACKGROUND OF THE INVENTION

### 1. Field of the Invention

The present invention generally relates to a detection system and a method thereof. In particular, the present invention pertains to a SAS connector conduction detecting system and a method thereof, wherein a SAS connector on each of two detection circuit boards is connected to one mainboard SAS connector of a mainboard respectively, and a test access port (TAP) controller and the two detection circuit boards are cascaded through a JTAG input connector and a JTAG output connector on each of the two detection circuit boards, so that the two detection circuit boards can provide the conduction detection for the mainboard SAS connectors correspondingly connected at the same time.

### 2. Description of the Related Art

The existing signal testing on the mainboard/SC SAS connector mainly uses the function test. Many dealers purchase a SAS test fixture to perform diagnosis by the high-speed differential communication between the SAS test fixture and the device under test. This test fixture is usually costly (it usually requires a more powerful MCU and peripheral circuits).

In summary, it can be seen that there is a problem in the prior art of excessive cost for a SAS connector detection. Therefore, it is necessary to propose an improved technical solution to solve this problem.

### SUMMARY OF THE INVENTION

In order to solve aforementioned problem in the prior art of excessive cost for a SAS connector detecting, the present invention discloses a SAS connector conduction detecting system and a method thereof.

The SAS connector conduction detecting system of the present invention includes a mainboard and two detection circuit boards. The mainboard includes a plurality of mainboard SAS connectors. Each of the plurality of mainboard SAS connectors on the mainboard is electrically connected to the mainboard SAS connector corresponding thereto.

Each detection circuit board includes a SAS connector, a JTAG input connector, a JTAG output connector, a buffer, a complex programmable logic device (CPLD), a first JTAG chip, a second JTAG chip, a first multiplexer, a second multiplexer, a microprocessor, an electrically-erasable programmable read-only memory (EEPROM), an analog-to-digital converter (ADC), and a voltage regulator, wherein the SAS connector is electrically connected to the CPLD, the first JTAG chip, the second JTAG chip, the ADC, and the voltage regulator respectively; the JTAG input connector is electrically connected to the JTAG output connector, the buffer, and the first multiplexer respectively; the JTAG output connector is electrically connected to the JTAG input connector and the first multiplexer respectively; the buffer is electrically connected to the JTAG input connector, the JTAG output connector, and the CPLD respectively; the CPLD is electrically connected to the buffer, the first JTAG chip, the SAS connector, and the microprocessor respectively; the first JTAG chip is electrically connected to the SAS connector, the CPLD, and the second JTAG chip respectively; the second JTAG chip is electrically connected to the SAS connector and the first JTAG chip respectively; the first multiplexer is electrically connected to the JTAG input connector, the JTAG output connector, the CPLD, and the microprocessor respectively; the second multiplexer is electrically connected to the microprocessor, the EEPROM, and the ADC respectively; the microprocessor is electrically connected to the CPLD, the first multiplexer, the second multiplexer, and the ADC respectively; the EEPROM is electrically connected to the second multiplexer; the ADC is electrically connected to the SAS connector, the second multiplexer, and the microprocessor respectively; and the voltage regulator is electrically connected to the first multiplexer and a power source respectively.

When each of the two detection circuit boards is connected to one of the plurality of mainboard SAS connectors of the mainboard corresponding thereto through its SAS connectors respectively, the two detection circuit boards provide the conduction detection for the mainboard SAS connectors of the mainboard correspondingly connected at the same time.

The SAS connector conduction detecting method of the present invention includes the following steps of: providing a mainboard having a plurality of mainboard SAS connectors; electrically connecting each of the plurality of mainboard SAS connectors on the mainboard to the mainboard SAS connector corresponding thereto; providing two detection circuit boards, each of the two detection circuit boards having a SAS connector, a JTAG input connector, a JTAG output connector, a buffer, a CPLD, a first JTAG chip, a second JTAG chip, a first multiplexer, a second multiplexer, a microprocessor, an EEPROM, an ADC, and a voltage regulator, wherein the SAS connector is electrically connected to the CPLD, the first JTAG chip, the second JTAG chip, the ADC, and the voltage regulator respectively; the JTAG input connector is electrically connected to the JTAG output connector, the buffer, and the first multiplexer respectively; the JTAG output connector is electrically connected to the JTAG input connector and the first multiplexer respectively; the buffer is electrically connected to the JTAG input connector, the JTAG output connector, and the CPLD respectively; the CPLD is electrically connected to the buffer, the first JTAG chip, the SAS connector, and the microprocessor respectively; the first JTAG chip is electrically connected to the SAS connector, the CPLD, and the second JTAG chip respectively; the second JTAG chip is electrically connected to the SAS connector and the first JTAG chip respectively; the first multiplexer is electrically connected to the JTAG input connector, the JTAG output connector, the CPLD, and the microprocessor respectively; the second multiplexer is electrically connected to the microprocessor, the EEPROM, and the ADC respectively; the microprocessor is electrically connected to the CPLD, the first multiplexer, the second multiplexer, and the ADC respectively; the EEPROM is electrically connected to the second multiplexer; the ADC is electrically connected to the SAS connector, the second multiplexer, and the microprocessor respectively; and the voltage regulator is electrically connected to the first multiplexer and a power source respectively; and providing, by the two detection circuit boards, the conduction detection for the mainboard SAS connectors of the mainboard correspondingly connected at the same time when connecting each of the two detection circuit boards to one of the plurality of mainboard SAS connectors of the mainboard corresponding thereto through its SAS connectors respectively.

The system and method disclosed by the present invention are as above, and the difference from the prior art is that the SAS connector on each of two detection circuit boards is connected to one mainboard SAS connector of the mainboard respectively, and a TAP controller and the two detection circuit boards are cascaded through the JTAG input connector and the JTAG output connector on each of the two detection circuit boards, so that the two detection circuit boards can provide the conduction detection for the mainboard SAS connectors correspondingly connected at the same time.

By aforementioned technology means, the present invention can achieve the technical technical effect in improving the detecting efficiency of the SAS connector.

### BRIEF DESCRIPTION OF THE DRAWINGS

The structure, operating principle and effects of the present invention will be described in detail by way of various embodiments which are illustrated in the accompanying drawings.

FIG. 1 is a block diagram of a SAS connector conduction detecting system according to the present invention.

FIG. 2A and FIG. 2B are flowcharts of a SAS connector conduction detecting method according to the present invention.

FIG. 3A to FIG. 3D are schematic views of a portion of the test blocks for SAS connector conduction detection according to the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. It is to be understood that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be understood that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present invention. As used herein, the term “or” includes any and all combinations of one or more of the associated listed items.

It will be understood that when an element is referred to as being “on,” “connected to” or “coupled to” another element, it can be directly on, connected or coupled to the other element, or intervening elements may be present. In contrast, when an element is referred to as being “directly on,” “directly connected to” or “directly coupled to” another element, there are no intervening elements present.

In addition, unless explicitly described to the contrary, the word “comprise” and variations such as “comprises” or “comprising”, will be understood to imply the inclusion of stated elements but not the exclusion of any other elements.

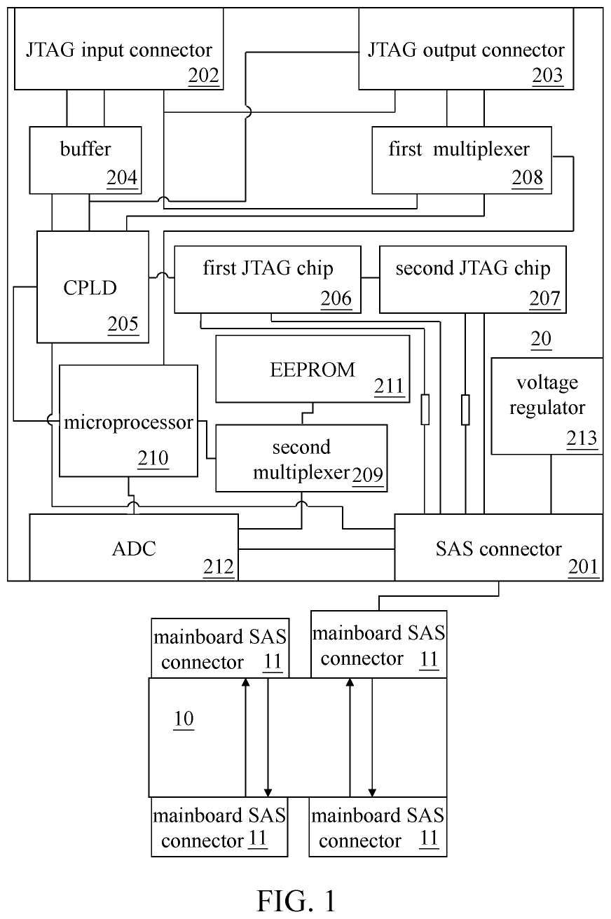

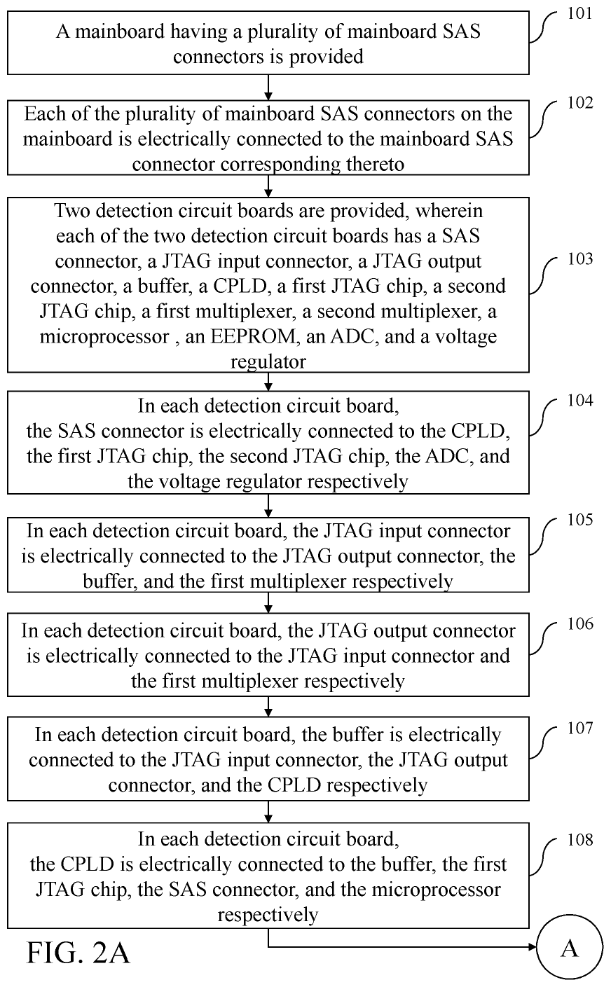

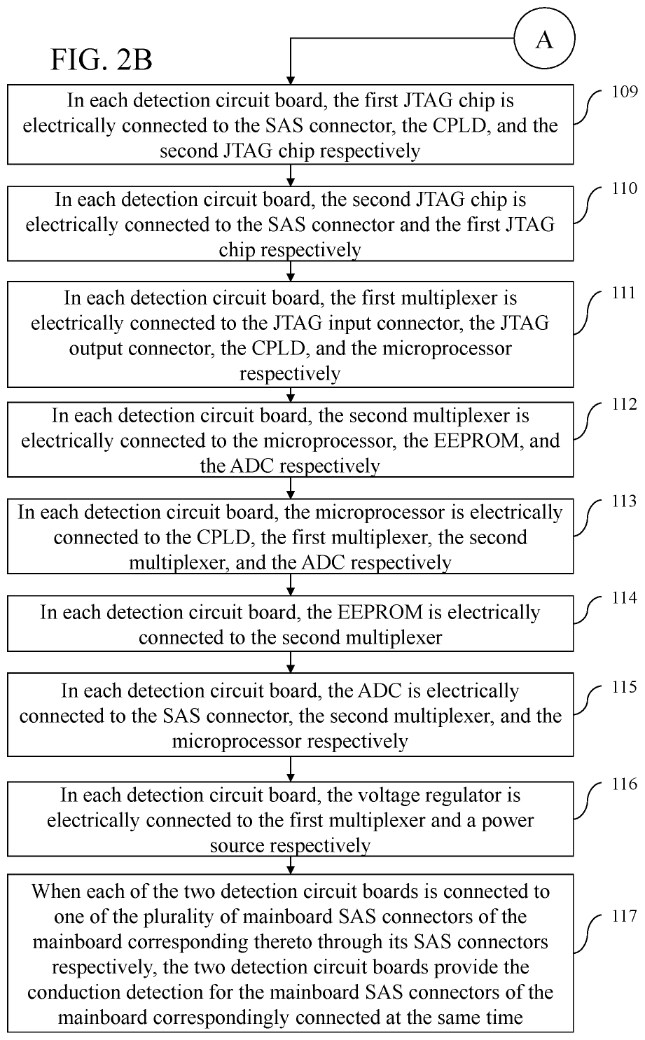

The operation of a SAS connector conduction detecting system of the present invention will be described below with reference to FIG. 1, FIG. 2A, and FIG. 2B, wherein FIG. 1 is a block diagram of a SAS connector conduction detecting system according to the present invention, and FIG. 2A and FIG. 2B are flowcharts of a SAS connector conduction detecting method according to the present invention.

The system of the present invention comprises a mainboard 10 and two detection circuit boards 20. The mainboard 10 comprises a plurality of mainboard SAS connectors 11. That is, the mainboard 10 has a plurality of mainboard SAS connectors 11 (step 101). Each of the plurality of mainboard SAS connectors 11 on the mainboard 10 is electrically connected to the mainboard SAS connector 11 corresponding thereto (step 102). Each detection circuit board 20 comprises a SAS connector 201, a JTAG input connector 202, a JTAG output connector 203, a buffer 204, a CPLD 205, a first JTAG chip 206, a second JTAG chip 207, a first multiplexer 208, a second multiplexer 209, a microprocessor 210, an EEPROM 211, an ADC 212, and a voltage regulator 213. That is, each of the two detection circuit boards 20 has a SAS connector 201, a JTAG input connector 202, a JTAG output connector 203, a buffer 204, a CPLD 205, a first JTAG chip 206, a second JTAG chip 207, a first multiplexer 208, a second multiplexer 209, a microprocessor 210, an EEPROM 211, an ADC 212, and a voltage regulator 213 (step 103).

In each detection circuit board 20, the SAS connector 201 of the detection circuit board 20 is electrically connected to the CPLD 205 of the detection circuit board 20, the first JTAG chip 206 of the detection circuit board 20, the second JTAG chip 207 of the detection circuit board 20, the ADC 212 of the detection circuit board 20, and the voltage regulator 213 of the detection circuit board 20 respectively (step 104).

In each detection circuit board 20, the JTAG input connector 202 of the detection circuit board 20 is electrically connected to the JTAG output connector 203 of the detection circuit board 20, the buffer 204 of the detection circuit board 20, and the first multiplexer 208 of the detection circuit board 20 respectively (step 105).

In each detection circuit board 20, the JTAG output connector 203 of the detection circuit board 20 is electrically connected to the JTAG input connector 202 of the detection circuit board 20 and the first multiplexer 208 of the detection circuit board 20 respectively (step 106).

In each detection circuit board 20, the buffer 204 of the detection circuit board 20 is electrically connected to the JTAG input connector 202 of the detection circuit board 20, the JTAG output connector 203 of the detection circuit board 20, and the CPLD 205 of the detection circuit board 20 respectively (step 107).

In each detection circuit board 20, the CPLD 205 of the detection circuit board 20 is electrically connected to the buffer 204 of the detection circuit board 20, the first JTAG chip 206 of the detection circuit board 20, the SAS connector 201 of the detection circuit board 20, and the microprocessor 210 of the detection circuit board 20 respectively (step 108).

In each detection circuit board 20, the first JTAG chip 206 of the detection circuit board 20 is electrically connected to the SAS connector 201, the CPLD 205 of the detection circuit board 20, and the second JTAG chip 207 of the detection circuit board 20 respectively (step 109).

In each detection circuit board 20, the second JTAG chip 207 of the detection circuit board 20 is electrically connected to the SAS connector 201 of the detection circuit board 20 and the first JTAG chip 206 of the detection circuit board 20 respectively (step 110).

In each detection circuit board 20, the first multiplexer 208 of the detection circuit board 20 is electrically connected to the JTAG input connector 202 of the detection circuit board 20, the JTAG output connector 203 of the detection circuit board 20, the CPLD 205 of the detection circuit board 20, and the microprocessor 210 respectively (step 111).

In each detection circuit board 20, the second multiplexer 209 of the detection circuit board 20 is electrically connected to the microprocessor 210, the EEPROM 211 of the detection circuit board 20, and the ADC 212 of the detection circuit board 20 respectively (step 112).

In each detection circuit board 20, the microprocessor 210 of the detection circuit board 20 is electrically connected to the CPLD 205 of the detection circuit board 20, the first multiplexer 208 of the detection circuit board 20, the second multiplexer 209 of the detection circuit board 20, and the ADC 212 of the test circuit board 20 respectively (step 113).

In each detection circuit board 20, the EEPROM 211 of the detection circuit board 20 is electrically connected to the second multiplexer 209 of the detection circuit board 20 (step 114).

In each detection circuit board 20, the ADC 212 of the detection circuit board 20 is electrically connected to the SAS connector 201 of the detection circuit board 20, the second multiplexer 209 of the detection circuit board 20, and the microprocessor 210 of the detection circuit board 20 respectively (step 115).

In each detection circuit board 20, the voltage regulator 213 of the detection circuit board 20 is electrically connected to the first multiplexer 208 of the detection circuit board 20 and a power source respectively (step 116).

The CPLD 205 of each detection circuit board 20 can be implemented by using a chip whose model number is EPM240. The first JTAG chip 206 of each detection circuit board 20 can be implemented by using a chip whose model number is SCAN15MB200TSQ. The second JTAG chip 207 of each detection circuit board 20 can be implemented by using a chip whose model number is SCAN15MB200TSQ. The first multiplexer 208 of each detection circuit board 20 can be implemented by using a chip whose model number is 74CBTLV3257, and the second multiplexer 209 of each detection circuit board 20 can be implemented by using a chip whose model number is PCA9548. The microprocessor 210 of each detection circuit board 20 can be implemented by using a chip whose model number is LPC 1113FBD48. The EEPROM 211 of each detection circuit board 20 can be implemented by using a chip whose model number is 24LC32AT. The ADC 212 of each detection circuit board 20 can be implemented by using a chip whose model number is MAX1039. The voltage regulator 213 of each detection circuit board 20 can be implemented by using a chip whose model number is IR3842. These are for illustrative purposes only and are not intended to limit the scope of application of the present invention.

In each detection circuit board 20, the first JTAG chip 206 of the detection circuit board 20 and the second JTAG chip 207 of the detection circuit board 20 provide a differential detecting signal and an input/output signal respectively. In each detection circuit board 20, the microprocessor 210 of the detection circuit board 20 is used to control the first JTAG chip 206 of the detection circuit board 20 or the second JTAG chip 207 of the detection circuit board 20 to generate the input/output signal and is used to control the switching for integrated circuit bus signals.

Each of the plurality of mainboard SAS connectors 11 on the mainboard 10 is electrically connected to the mainboard SAS connector 11 corresponding thereto, and the JTAG input connector 202 of each detection circuit board 20 can be connected with a TAP controller or the JTAG output connector 202 of another detection circuit board 20, and the JTAG output connector 203 of each detection circuit board 20 is electrically connected to the JTAG input connector 202 of the other detection circuit board 20 or is unconnected. When one mainboard SAS connector 11 of the mainboard 10 and the mainboard SAS connector 11 corresponding thereto are electrically connected to the SAS connector 201 of each detection circuit board 20 respectively, the TAP controller provides a detection signal to the detection circuit boards 20 corresponding thereto, and the conduction detection of the connector pins is performed on the two mainboard SAS connectors 11 corresponding to the mainboard 10 according to the detection signal through the two detection circuit boards 20 corresponding thereto at the same time (step 117).

Each mainboard SAS connector 11 of the mainboard 10 and the SAS connector 201 of each detection circuit board 20 include integrated circuit buses, input/output pins, ground pins, data transfer pins, and analog signal pins respectively. This is for illustrative purposes only and is not intended to limit the scope of application of the present invention. That is, the detection signal is used to detect conduction including differential signal pin detection, ground signal pin detection, analog signal pin detection, input/output pin detection, and integrated circuit bus pin detection on each mainboard SAS connector 11 of the mainboard 10.

When the conduction detecting of the pins of the mainboard SAS connector 11 of the mainboard 10 is performed, the TAP controller sets the CPLD 205 of the detection circuit board 20, the first JTAG chip 206 of the detection circuit board 20, and the second JTAG chip 207 of the detection circuit board 20 to be in the boundary scan mode.

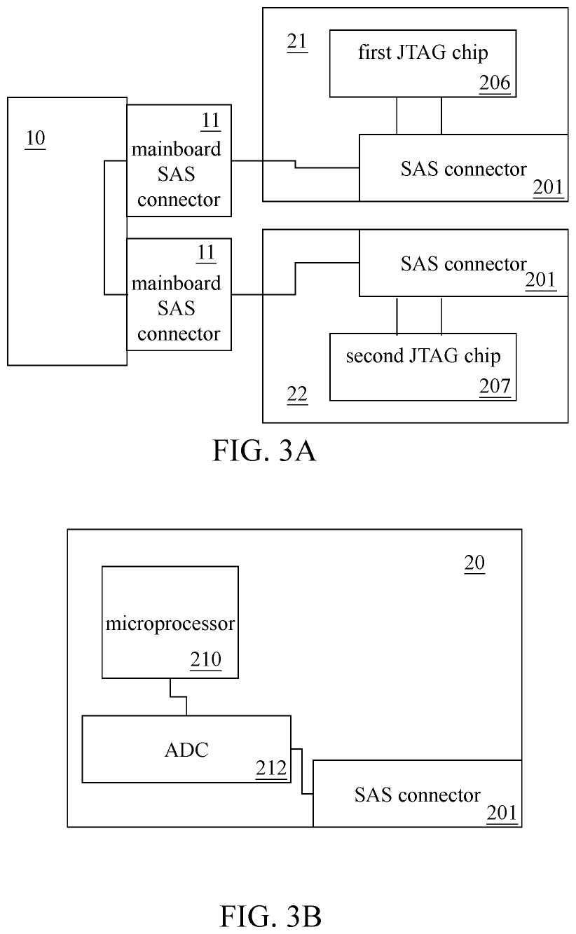

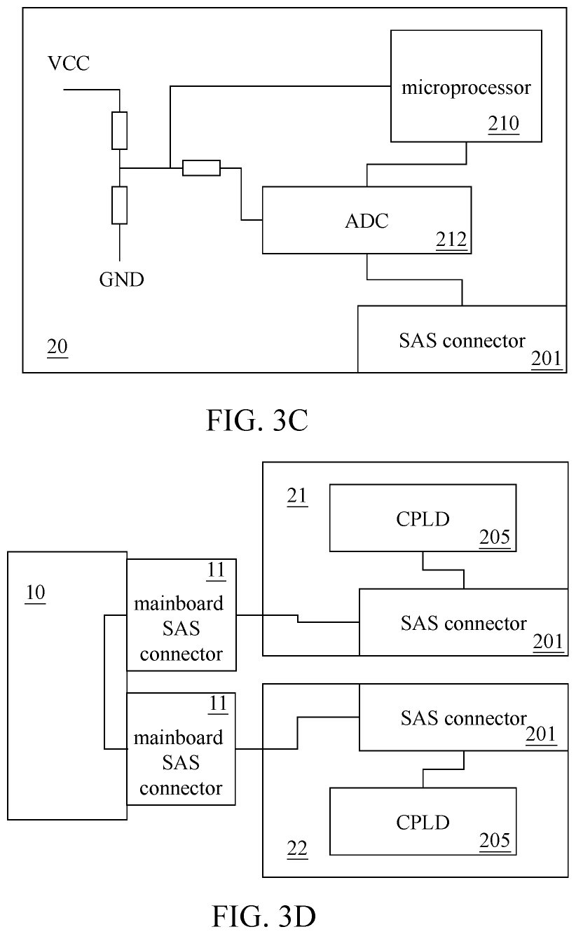

Please refer to FIG. 3A, and FIG. 3A is a schematic view of a portion of the test blocks for SAS connector conduction detecting according to the present invention.

In each detection circuit board 20, the CPLD 205 of the detection circuit board 20, the first JTAG chip 206 of the detection circuit board 20, the second JTAG chip 207 of the detection circuit board 20, and the microprocessor 210 of the detection circuit board 20 generate a differential signal or perform signal control according to the detecting signal.

In the signal detection of the PE_TX_DP pin (that is, the data transfer pin) and the PE_TX_DN pin (that is, the data transfer pin) in the mainboard SAS connector 11, the differential signal is generated by the first JTAG chip 206 or the second JTAG chip 207 of the first detection circuit board 21, and is transmitted to the first JTAG chip 206 or the second JTAG chip 207 of the second detection circuit board 22 through the SAS connector 201 of first detection circuit board 21, the mainboard SAS connector 11 of the mainboard 10, and the SAS connector 201 of second detection circuit board 22 for detection when the first JTAG chip 206 or the second JTAG chip 207 of the first detection circuit board 21 receives the detection signal.

If the differential signal sent by the first JTAG chip 206 or the second JTAG chip 207 of the first detection circuit board 21 coincides with the differential signal received by the first JTAG chip 206 or the second JTAG chip 207 of the second detection circuit board 22, the conduction detection of the PE_TX_DP pin and the PE_TX_DN pin in the mainboard SAS connector 11 passes. Conversely, if the differential signal sent by the first JTAG chip 206 or the second JTAG chip 207 of the first detection circuit board 21 does not coincide with the differential signal received by the first JTAG chip 206 or the second JTAG chip 207 of the second detection circuit board 22, the conduction detection of the PE_TX_DP pin and the PE_TX_DN pin in the mainboard SAS connector 11 fails.

In the signal detection of the PE_RX_DP pin (that is, the data transfer pin) and the PE_RX_DN pin (that is, the data transfer pin) in the mainboard SAS connector 11, the differential signal is generated by the first JTAG chip 206 or the second JTAG chip 207 of the second detection circuit board 22, and is transmitted to the first JTAG chip 206 or the second JTAG chip 207 of the first detection circuit board 21 through the SAS connector 201 of the second detection circuit board 22, the mainboard SAS connector 11 of the mainboard 10, and the SAS connector 201 of the first detection circuit board 21 for detection when the first JTAG chip 206 or the second JTAG chip 207 of the second detection circuit board 22 receives the detection signal.

If the differential signal sent by the first JTAG chip 206 or the second JTAG chip 207 of the second detection circuit board 22 coincides with the differential signal received by the first JTAG chip 206 or the second JTAG chip 207 of the first detection circuit board 21, the conduction detection of the PE_RX_DP pin and the PE_RX_DN pin in the mainboard SAS connector 11 passes. Conversely, if the differential signal sent by the first JTAG chip 206 or the second JTAG chip 207 of the second detection circuit board 22 does not coincide with the differential signal received by the first JTAG chip 206 or the second JTAG chip 207 of the first detection circuit board 21, the conduction detection of the PE_RX_DP pin and the PE_RX_DN pin in the mainboard SAS connector 11 fails.

Please refer to FIG. 3B and FIG. 3C, and FIG. 3B and FIG. 3C are schematic views of a portion of the test blocks for SAS connector conduction detecting according to the present invention

The signal detection of the analog signal pins in the mainboard SAS connector 11 comprises the following steps. When the microprocessor 210 of the detection circuit board 20 receives the detection signal, the microprocessor 210 of the detection circuit board 20 is connected to the ADC 212 of the detection circuit board 20 through the integrated circuit bus. After the ADC 212 of the detection circuit board 20 reads the voltage value of the analog signal pins in the mainboard SAS connector 11, the microprocessor 210 of the detection circuit board 20 stores the voltage value of the analog signal pins in the mainboard SAS connector 11 read by the ADC 212 of the detection circuit board 20, and the microprocessor 210 of the detection circuit board 20 determines whether the detection result is correct according to the voltage value, thereby determining whether the analog signal pins in the mainboard SAS connector 11 are conductive.

It is worth noting that when the power source is open, the analog signal pins of the ADC 212 are in a null state, and the voltage of the analog signal pins of the ADC 212 is not in the steady state. In order to avoid the unstable voltage of the analog signal pins of the ADC 212, which are in the null state at the time of signal detection, pull-down resistors are connected to the analog signal pins of the ADC 212 respectively if there is no pull-down resistor connected to the analog signal pins of the ADC 212. The aforementioned pull-down resistor may have a resistance value ranging from 3M ohms to 4M ohms, which is merely illustrative and is not intended to limit the scope of application of the present invention.

Further, a resistive divider circuit is connected to the microprocessor 210 of each detection circuit board 20 and the ADC 212 of each detection circuit board 20 respectively. For example, the resistive divider circuit comprises 10M ohms resistor and 2M ohms resistor connected in series, which is merely illustrative here, and is not limited to the scope of application of the present invention. A backup line can be disposed between the resistive divider circuit and the ADC 212 of the detection board 20. That is, a 0-ohm resistor is connected in series between the resistive divider circuit and the ADC 212 of the detection board 20, as described in FIG. 3C.

Please refer to FIG. 3D, and FIG. 3D is a schematic view of a portion of the test blocks for SAS connector conduction detecting according to the present invention.

In the signal detection of the REFCLK_DP pin (that is, the clock pin) and REFCLK_DN pin (that is, the clock pin) in the mainboard SAS connector 11, the CPLD 205 of the first detection board 21 sends detection data to the CPLD 205 of the second detection board 22 according to the detection signal. If the detection data sent by the CPLD 205 of the first detection board 21 coincides with the detection data received by the CPLD 205 of the second detection board 22, the signal detection of the REFCLK_DP pin and REFCLK_DN pin in the mainboard SAS connector 11 passes. Conversely, if the detection data sent by the CPLD 205 of the first detection board 21 does not coincide with the detection data received by the CPLD 205 of the second detection board 22, the signal detection of the REFCLK_DP pin and REFCLK_DN pin in the mainboard SAS connector 11 fails.

In other embodiment, in the signal detection of the REFCLK_DP pin (that is, the clock pin) and REFCLK_DN pin (that is, the clock pin) in the mainboard SAS connector 11, the CPLD 205 of the second detection board 22 sends detection data to the CPLD 205 of the first detection board 21 according to the detection signal. If the detection data sent by the CPLD 205 of the second detection board 22 coincides with the detection data received by the CPLD 205 of the first detection board 21, the signal detection of the REFCLK_DP pin and REFCLK_DN pin in the mainboard SAS connector 11 passes. Conversely, if the detection data sent by the CPLD 205 of the second detection board 22 does not coincide with the detection data received by the CPLD 205 of the first detection board 21, the signal detection of the REFCLK_DP pin and REFCLK_DN pin in the mainboard SAS connector 11 fails.

In summary, it can be seen that the difference between the present invention and the prior art is that the SAS connector on each of two detection circuit boards is connected to one mainboard SAS connector of the mainboard respectively, and a TAP controller and the two detection circuit boards are cascaded through the JTAG input connector and the JTAG output connector on each of the two detection circuit boards, so that the two detection circuit boards can provide the conduction detection for the mainboard SAS connectors correspondingly connected at the same time.

Above-mentioned technical means can be used to solve the problem of excessive cost for a SAS connector detecting in the prior art, so as to achieve the technical effect of improving the detecting efficiency of the SAS connector.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A SAS connector conduction detecting system, comprising:
a mainboard, comprising:
a plurality of mainboard SAS connectors, wherein each of the plurality of mainboard SAS connectors is electrically connected to the mainboard SAS connector corresponding thereto; and
two detection circuit boards, each of the two detection circuit boards comprising a SAS connector, a JTAG input connector, a JTAG output connector, a buffer, a CPLD, a first a JTAG chip, a second JTAG chip, a first multiplexer, a second multiplexer, a microprocessor, an EEPROM, an ADC, and a voltage regulator, wherein in each of the two detection circuit boards:
the SAS connector is electrically connected to the CPLD, the first JTAG chip, the second JTAG chip, the ADC, and the voltage regulator respectively;
the JTAG input connector is electrically connected to the JTAG output connector, the buffer, and the first multiplexer respectively;
the JTAG output connector is electrically connected to the JTAG input connector and the first multiplexer respectively;
the buffer is electrically connected to the JTAG input connector, the JTAG output connector, and the CPLD respectively;
the CPLD is electrically connected to the buffer, the first JTAG chip, the SAS connector, and the microprocessor respectively;
the first JTAG chip is electrically connected to the SAS connector, the CPLD, and the second JTAG chip respectively;
the second JTAG chip is electrically connected to the SAS connector and the first JTAG chip respectively;
the first multiplexer is electrically connected to the JTAG input connector, the JTAG output connector, the CPLD, and the microprocessor respectively;
the second multiplexer is electrically connected to the microprocessor, the EEPROM, and the ADC respectively;
the microprocessor is electrically connected to the CPLD, the first multiplexer, the second multiplexer, and the ADC respectively;
the EEPROM is electrically connected to the second multiplexer;
the ADC is electrically connected to the SAS connector, the second multiplexer, and the microprocessor respectively;
the voltage regulator is electrically connected to the first multiplexer and a power source respectively; and
when each of the two detection circuit boards is connected to one of the plurality of mainboard SAS connectors of the mainboard corresponding thereto through its SAS connectors respectively, the two detection circuit boards provide the conduction detection for the mainboard SAS connectors of the mainboard correspondingly connected at the same time.

2. The system according to claim 1, wherein the JTAG input connector of each of the two detection circuit boards is electrically connected to a TAP controller or the JTAG output connector of another detection circuit board; and the JTAG output connector of each of the two detection circuit boards is electrically connected to the JTAG input connector of the other detection circuit board.

3. The system according to claim 1, wherein each of the plurality of mainboard SAS connector and the SAS connector comprise integrated circuit buses, input/output pins, ground pins, data transfer pins, and analog signal pins respectively.

4. The system according to claim 1, wherein the conduction detection of each of the plurality of mainboard SAS connectors comprises data transfer pin detection, analog signal pin detection, and clock pin detection.

5. The system according to claim 1, wherein the CPLD and the microprocessor are set to be in a boundary scan mode by a TAP controller.

6. A SAS connector conduction detecting method, comprising:
providing a mainboard having a plurality of mainboard SAS connectors;
electrically connecting each of the plurality of mainboard SAS connectors on the mainboard to the mainboard SAS connector corresponding thereto;
providing two detection circuit boards, each of the two detection circuit boards having a SAS connector, a JTAG input connector, a JTAG output connector, a buffer, a CPLD, a first JTAG chip, a second JTAG chip, a first multiplexer, a second multiplexer, a microprocessor, an EEPROM, an ADC, and a voltage regulator, wherein:
the SAS connector is electrically connected to the CPLD, the first JTAG chip, the second JTAG chip, the ADC, and the voltage regulator respectively;
the JTAG input connector is electrically connected to the JTAG output connector, the buffer, and the first multiplexer respectively;
the JTAG output connector is electrically connected to the JTAG input connector and the first multiplexer respectively;
the buffer is electrically connected to the JTAG input connector, the JTAG output connector, and the CPLD respectively;
the CPLD is electrically connected to the buffer, the first JTAG chip, the SAS connector, and the microprocessor respectively;
the first JTAG chip is electrically connected to the SAS connector, the CPLD, and the second JTAG chip respectively;
the second JTAG chip is electrically connected to the SAS connector and the first JTAG chip respectively;
the first multiplexer is electrically connected to the JTAG input connector, the JTAG output connector, the CPLD, and the microprocessor respectively;
the second multiplexer is electrically connected to the microprocessor, the EEPROM, and the ADC respectively;
the microprocessor is electrically connected to the CPLD, the first multiplexer, the second multiplexer, and the ADC respectively,
the EEPROM is electrically connected to the second multiplexer;
the ADC is electrically connected to the SAS connector, the second multiplexer, and the microprocessor respectively; and
the voltage regulator is electrically connected to the first multiplexer and a power source respectively, and
providing, by the two detection circuit boards, the conduction detection for the mainboard SAS connectors of the mainboard correspondingly connected at the same time when connecting each of the two detection circuit boards to one of the plurality of mainboard SAS connectors of the mainboard corresponding thereto through its SAS connectors respectively.

7. The method according to claim 6, wherein the JTAG input connector of each of the two detection circuit boards is electrically connected to a TAP controller or the JTAG output connector of another detection circuit board, and the JTAG output connector of each of the two detection circuit boards is electrically connected to the JTAG input connector of the other detection circuit board.

8. The method according to claim 6, wherein each of the plurality of mainboard SAS connector and the SAS connector comprise integrated circuit buses, input/output pins, ground pins, data transfer pins, and analog signal pins respectively.

9. The method according to claim 6, wherein the conduction detection of each of the plurality of mainboard SAS connectors comprises data transfer pin detection, analog signal pin detection, and clock pin detection.

10. The method according to claim 6, wherein the CPLD and the microprocessor are set to be in a boundary scan mode by a TAP controller.
